(19) United States
(12) Patent Application Publication
(10) Pub. No.: US 2022/0005765 A1
(43) Pub. Date: Jan. 6, 2022

(54) SUBSTRATE STRUCTURE

(71) Applicant: SAMSUNG ELECTRO-MECHANICS CO., LTD., Suwon-si (KR)

(72) Inventors: Moon Hee Yi, Suwon-si (KR); Yong Hoon Kim, Suwon-si (KR); Yun Je Ji, Suwon-si (KR); Seon Ha Kang, Suwon-si (KR)

(21) Appl. No.: 17/083,901

(22) Filed: Oct. 29, 2020

(30) Foreign Application Priority Data
Jul. 3, 2020 (KR) 10-2020-0082017

(51) Int. Cl. H01L 23/538; H01L 25/065; H01L 23/00; H01L 23/498

(52) U.S. Cl. CPC H01L 23/5385; H01L 25/0655; H01L 23/49816; H01L 23/5384; H01L 23/5386; H01L 24/14

(57) ABSTRACT

A substrate structure may include a printed circuit board including a first recess and a first junction pad disposed on a lower surface of the first recess; a first electronic component package disposed in the first recess, and including a first substrate and a first electronic device module disposed on at least one surface of the first substrate; and a first external junction portion connecting the first electronic component package and the first junction pad.

### CROSS-REFERENCE TO RELATED APPLICATION(S)

This application claims benefit of priority to Korean Patent Application No. 10-2020-0082017 filed on Jul. 3, 2020 in the Korean Intellectual Property Office, the disclosure of which is incorporated herein by reference in its entirety.

### TECHNICAL FIELD

The present disclosure relates to a substrate structure including a printed circuit board, and an electronic component package mounted on the printed circuit board.

### BACKGROUND

An electronic component package refers to a package technology for electrically connecting an electronic component to a printed circuit board (PCB), for example, a mainboard of an electronic device, or the like, and protecting the electronic component from external impacts.

With the recent trend toward the miniaturization of components, requirements to implement a fine pitch of electronic components, and to implement weight-lighting, thickness-reducing, distance-shortening, and small-sizing of a printed circuit board are increasing.

To this end, there may be a need to reduce a mounting region of electronic components and an overall thickness of a printed circuit board without reducing a gap between electronic components or reducing a thickness of the electronic component itself.

In addition, a need to more effectively shield electromagnetic waves or the like, mutually affecting electronic component packages in a small-sized printed circuit board, is increasing.

### SUMMARY

An aspect of the present disclosure is to reduce a mounting region of electronic components and an overall thickness of a printed circuit board.

Another aspect of the present disclosure is to improve shielding characteristics between electronic component packages in a small-sized printed circuit board.

According to an aspect of the present disclosure, a substrate structure includes a printed circuit board including a first recess and a first junction pad disposed on a lower surface of the first recess; a first electronic component package disposed in the first recess, and including a first substrate and a first electronic device module disposed on at least one surface of the first substrate; and a first external junction portion connecting the first electronic component package and the first junction pad.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 schematically illustrates an example of a block diagram of an electronic device system.

FIG. 2 schematically illustrates a perspective view of an electronic device.

FIG. 3 is a view schematically illustrating a substrate structure according to a first embodiment of the present disclosure.

FIG. 4 is a view schematically illustrating a substrate structure according to a second embodiment of the present disclosure.

FIG. 5 is a view schematically illustrating a substrate structure according to a third embodiment of the present disclosure.

FIG. 6 is a view schematically illustrating an electronic component package according to the first embodiment of the present disclosure.

FIG. 7 is a view schematically illustrating an electronic component package according to a first modified example of the first embodiment of the present disclosure.

FIG. 8 is a view schematically illustrating an electronic component package according to a second modified example of the first embodiment of the present disclosure.

FIG. 9 is a schematic diagram illustrating an electronic component package according to a third modified example of the first embodiment of the present disclosure.

FIG. 10 is a view schematically illustrating an electronic component package according to a fourth modified example of the first embodiment of the present disclosure.

FIG. 11 is a schematic diagram illustrating an electronic component package according to a fifth modified example of the first embodiment of the present disclosure.

FIGS. 12 to 16 are process cross-sectional views schematically illustrating an example method of manufacturing the electronic component package of FIG. 6.

### DETAILED DESCRIPTION

Hereinafter, the present disclosure will be described with reference to the accompanying drawings. In the drawings, shapes, sizes, and the like of elements may be exaggerated or reduced for more clarity.

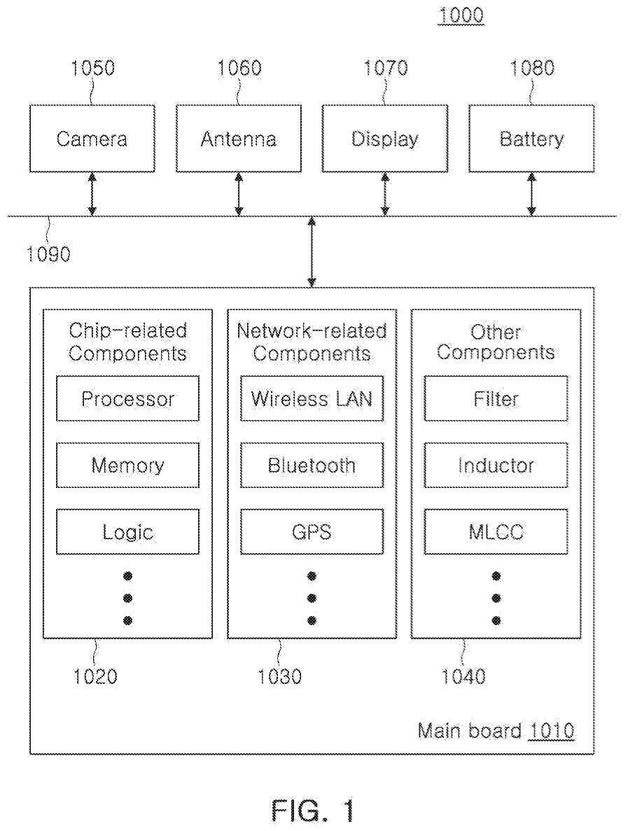

FIG. 1 schematically illustrates an example of a block diagram of an electronic device system.

Referring to the drawings, an electronic device 1000 may accommodate a mainboard 1010 therein. The mainboard 1010 may include chip related components 1020, network related components 1030, other components 1040, and the like, physically and/or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related components. In addition, the chip related components 1020 may be combined with each other. The chip related component 1020 may be in the form of a package including the above-described chip.

The network related components 1030 may include protocols such as wireless fidelity (Wi-Fi) (Institute of Electrical and Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with the chip related components 1020, and may be provided in a package form.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with the chip related components 1020 and/or the network related components 1030, and may be provided in a package form.

Depending on a type of the electronic device 1000, the electronic device 1000 may include other components that may or may not be physically and/or electrically connected to the mainboard 1010. These other components may include, for example, a camera module 1050, an antenna module 1060, a display device 1070, a battery 1080, or the like. However, these other components are not limited thereto, but may also include an audio codec, a video codec, a power amplifier, a compass, an accelerometer, a gyroscope, a speaker, amass storage unit (for example, a hard disk drive), a compact disk (CD) drive, a digital versatile disk (DVD) drive, or the like. These other components may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

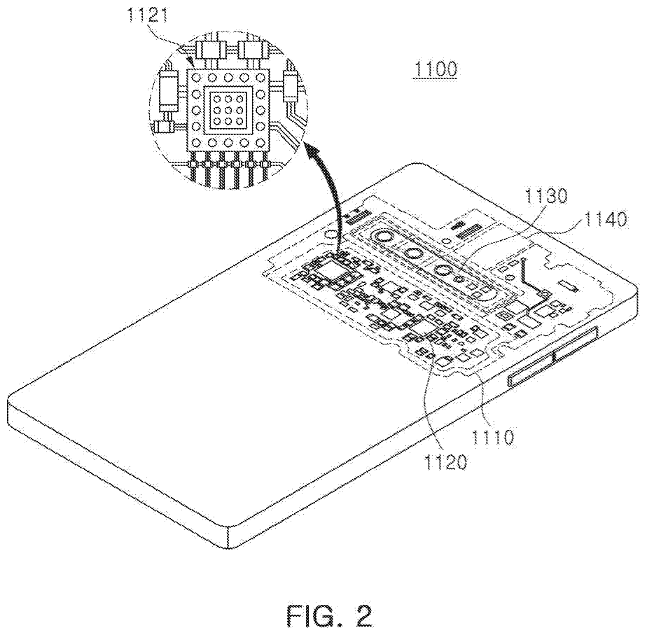

FIG. 2 schematically illustrates a perspective view of an electronic device.

Referring to the drawings, an electronic device may be, for example, a smartphone 1100. The mainboard 1110 may be accommodated in the smartphone 1100, and various electronic components 1120 may be physically and/or electrically connected to the mainboard 1110. In addition, other electronic components, such as a camera package 1130 and/or a speaker 1140 may be accommodated therein. A portion of the electronic components 1120 may be the above-described chip related components, for example, a component package 1121, but are not limited thereto. The component package 1121 may be one in which a plurality of electronic components are disposed on a multilayer printed circuit board in a form of surface mounting, but is not limited thereto. The electronic device is not necessarily limited to the smartphone 1100, and may be other electronic devices as described above.

### First Embodiment

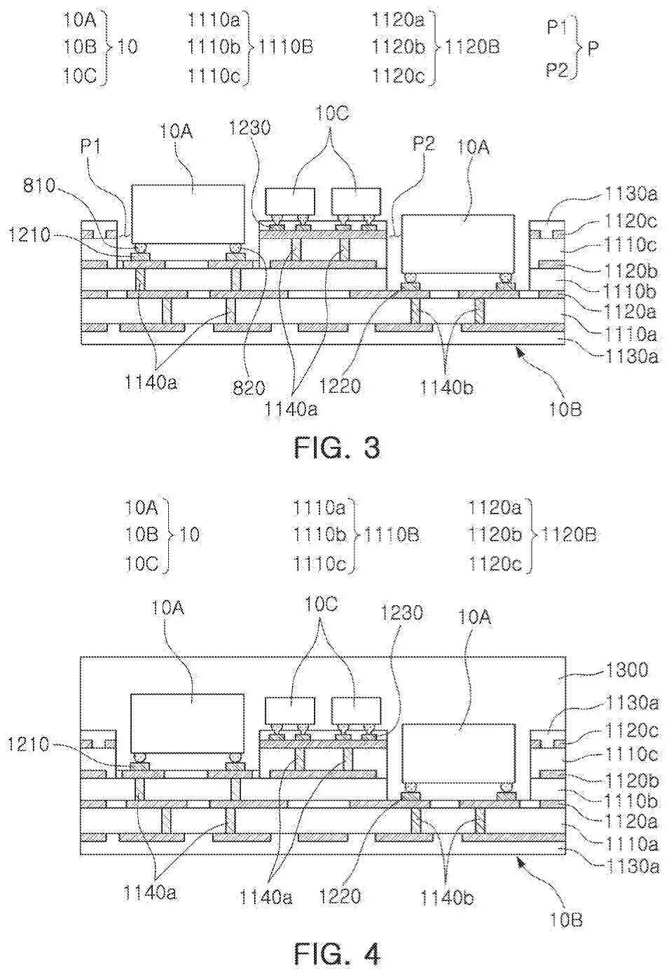

FIG. 3 is a view schematically illustrating a substrate structure according to a first embodiment of the present disclosure.

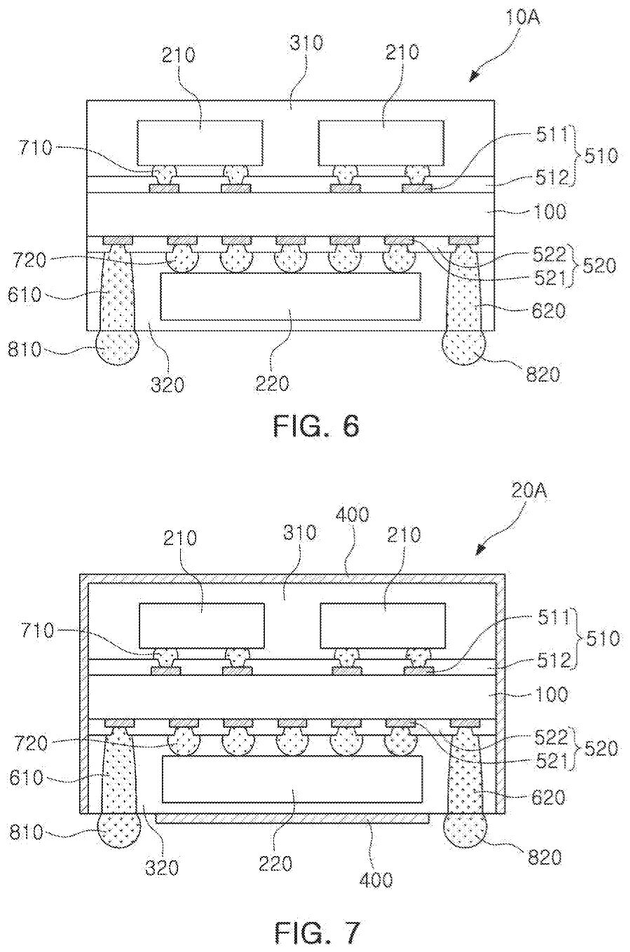

FIG. 6 is a view schematically illustrating an electronic component package according to the first embodiment of the present disclosure.

Electronic Component Package

Referring to the drawings, a first electronic component package 10A according to the first embodiment of the present disclosure may include a first substrate 100, first electronic device module (210 and 220), first and second encapsulation portions 310 and 320, first and second connection structures 510 and 520, and first and second connection electrodes 610 and 620.

The first substrate 100 may have one surface and the other surface, opposing each other. In this embodiment, the one surface of the first substrate 100 may refer to an upper surface of the first substrate 100, based on a thickness direction thereof, and the other surface of the first substrate 100 refers to a lower surface of the first substrate 100, based on the thickness direction thereof. The first substrate 100 may be in a form of a core type, but is not limited thereto.

An insulating material may be used as a material of the first substrate 100. As the insulating material, a thermosetting resin such as an epoxy resin, or a thermoplastic resin such as polyimide, and those including a reinforcing material such as an inorganic filler such as silica and/or glass fiber, etc in the resins may be used. For example, as the material of the first substrate 100, a copper clad laminate (CCL) or a prepreg may be used.

The first electronic device module (210 and 220) may be disposed on the one surface and the other surface of the first substrate 100, respectively. In this embodiment, the first electronic device module (210 and 220) may include a first electronic device 210 disposed on the one surface of the first substrate 100, and a second electronic device 220 disposed on the other surface of the first substrate 100. The first electronic device 210 may include a passive device, and the second electronic device 220 may include an active device. The passive device may be a chip-type passive component, and may be, for example, a high frequency inductor, a ferrite inductor, a power inductor, a ferrite bead, an LTCC, an EMI filter, an MLCC, or the like. The active device may be a semiconductor chip in a form of an integrated circuit (IC) in which hundreds to millions of devices are integrated in a single chip. The semiconductor chip may be a logic chip or a memory chip. The logic chip may be a CPU, a GPU, or the like, an AP including at least one of a CPU or a GPU, an analog-to-digital converter, an ASIC, or the like, or a chip set including a specific combination of those listed so far. The memory chip may be a stack memory such as HBM or the like. In this embodiment, as the first electronic device 210 and the second electronic device 220 are arranged to oppose each other on both surfaces of the first substrate 100, the passive device and the active device may be arranged to oppose each other on the both surfaces of the first substrate 100. As a result, amounting region in which the electronic component package is mounted on the printed circuit board may be reduced without reducing a separation distance between the electronic components, based on a horizontal direction.

The first encapsulation portion 310 may be disposed on the one surface of the first substrate 100 to cover the first electronic device 210. The second encapsulation portion 320 may be disposed on the other surface of the first substrate 100 to cover the second electronic device 220. Referring to FIG. 6, the first electronic component package 10A according to this embodiment may include both a first encapsulation portion 310 and a second encapsulation portion 320. Although not specifically illustrated, the first and second encapsulation portions 310 and 320 may be optionally formed, and only one of the first encapsulation portion 310 or the second encapsulation portion 320 may be included.

In this manner, the first and second electronic devices 210 and 220 may be encapsulated by the first and second encapsulation portions 310 and 320, respectively, to prevent an occurrence of an electrical short between the first and second electronic devices 210 and 220, and fix the first and second electronic devices 210 and 220 on the first substrate 100. As a result, breakage and separation of the first and second electronic devices 210 and 220 by external impact may be prevented.

A material of the first and second encapsulation portions 310 and 320 is not particularly limited as long as it has insulating properties. For example, a thermosetting resin such as an epoxy resin, a thermoplastic resin such as polyimide, or resins including reinforcing materials such as glass fiber, glass cloth, glass fabric and/or inorganic fillers, together with these, such as a prepreg, Ajinomoto Build-up Film (ABF), and the like may be used.

The first electronic component package 10A of this embodiment may include a first connection structure 510 formed on the one surface and disposed between the first substrate 100 and the first electronic device 210, and a second connection structure 520 formed on the other surface of the first substrate 100 and disposed between the first substrate 100 and the second electronic device 220.

Referring to FIG. 6, the first connection structure 510 may include a first connection pad 511 disposed on the one surface of the first substrate 100, and a first passivation layer 512 disposed on the one surface of the first substrate 100 and partially covering the first connection pad 511. The second connection structure 520 may include a second connection pad 521 disposed on the other surface of the first substrate 100, and a second passivation layer 522 disposed on the other surface of the first substrate 100 and partially covering the second connection pad 521. The first passivation layer 512 may cover at least a portion of lateral and upper surfaces of the first connection pad 511. The second passivation layer 522 may cover at least a portion of lateral and lower surfaces of the second connection pad 521. As a result, they may be protected from external physical and chemical damage or the like. In particular, when the first encapsulation portion 310 or the second encapsulation portion 320 are not formed, a wiring layer (not illustrated) or the connection pads 511 and 521 to be described later may be protected from an external environment. A material of the first and second passivation layers 512 and 522 may be an insulating material. In this case, as the insulating material, a thermosetting resin such as an epoxy resin, a thermoplastic resin such as polyimide, or a mixture of these resins and an inorganic filler, e.g., ABF may be used, but the present disclosure is not limited thereto, and a solder resist (SR) including a photosensitive material may be used. As necessary, the first and second passivation layers 512 and 522 may have openings exposing at least a portion of each of the first connection pad 511 and the second connection pad 521.

Although not specifically illustrated, the first substrate 100 may include a wiring layer (not illustrated) therein. A metal material may be used as a material for the wiring layer (not illustrated), and as the metal material, copper (Cu), aluminum (Al), silver (Ag), tin (Sn), gold (Au), nickel (Ni), lead (Pb), titanium (Ti), or an alloy thereof may be used. The wiring layer (not illustrated) may perform various functions, depending on a design. For example, a ground pattern, a power pattern, a signal pattern, and the like may be included. In this case, the signal pattern may include various signals, excluding the ground pattern and the power pattern, for example, a data signal, and the like. Each of these patterns may have a line pattern, a plane pattern, or a pad pattern. The wiring layer (not illustrated) may be formed with a plating process, and, as a result, may include a seed layer that may be an electroless plating layer, and an electroplating layer formed based on the seed layer.

First and second internal junction portions 710 and 720 may be formed between the first and second electronic devices 210 and 220 and the first substrate 100, respectively. The first and second internal junction portions 710 and 720 may connect the first electronic device 210 to the first connection structure 510 and the second electronic device 220 to the second connection structure 520, respectively, in the first electronic component package 10A. The first and second internal junction portions 710 and 720 may be formed of a solder ball.

The first and second connection electrodes 610 and 620 may be disposed on the other surface of the first substrate 100 to connect the first substrate 100 and a first junction pad 1210. The first and second connection electrodes 610 and 620 may be formed of solder.

In this embodiment, for convenience of explanation, only the first electronic component package 10A may be described, but the same description may also be applied to a second electronic component package 10A. For example, the second electronic component package 10A may include a second substrate and a second electronic device module formed on at least one surface of the second substrate, and may be disposed in a second recess P2 to be described later.

Printed Circuit Board

In addition, referring to the drawings, a printed circuit board 10B of the first embodiment of the present disclosure may include first and second recesses P1 and P2 and first and second junction pads 1210 and 1220.

A substrate structure 10 of this embodiment may include a printed circuit board 10B having a recess P (e.g., P1 and P2) accommodating an electronic component package 10A. Referring to FIG. 3, a printed circuit board 10B may include an insulating portion 1110B including a plurality of insulating layers 1110a, 1110b, and 1110c, and a wiring portion 1120B including a plurality of wiring layers 1120a, 1120b, and 1120c. The printed circuit board 10B may be a multilayer board formed by repeatedly stacking the plurality of insulating layers 1110a, 1110b, and 1110c and the plurality of wiring layers 1120a, 1120b, and 1120c. As necessary, the printed circuit board 10B may be provided as a double-sided substrate with wiring layers formed on both surfaces of a single insulating layer. In addition, when the electronic component packages 10A is provided as a plurality of electronic component packages, the printed circuit board 10B may have first and second recesses P1 and P2 for accommodating first and second electronic component packages 10A, respectively. In this embodiment, one surface of the printed circuit board 10B may refer to an upper surface of the printed circuit board 10B, based on a thickness direction of the substrate structure 10. Specifically, the one surface of the printed circuit board 10B may refer to an uppermost surface of the printed circuit board 10B in the thickness direction, formed along the first and second recesses P1 and P2, among surfaces of the printed circuit board 10B. Referring to FIG. 3, the first and second recesses P1 and P2 may be arranged to be spaced apart from each other on the one surface of the printed circuit board 10B.

In this embodiment, the recesses P1 and P2 may be formed by processing a partial region of the plurality of insulating layers 1110a, 1110b, and 1110c with a laser. For example, only a partial layer of the plurality of insulating layers 1110a, 1110b, and 1110c may be processed, or only a partial region of a single layer of the plurality of insulating layers 1110a, 1110b, and 1110c may be processed. In addition, when the plurality of insulating layers 1110a, 1110b, and 1110c are stacked, only a partial layer of the plurality of insulating layers 1110a, 1110b, and 1110c may be stacked, or only a partial region of a single layer of the plurality of insulating layers 1110a, 1110b, and 1110c may not be stacked, to form the recess P. In this case, the first and second recesses P1 and P2 may be formed to partially pass through the plurality of insulating layers 1110a, 1110b, and 1110c. When the plurality of insulating layers 1110a, 1110b, and 1110c are processed or stacked in this manner to form the first and second recesses P1 and P2, depths of the first and second recesses P1 and P2 may be the same or different. A method of stacking the plurality of insulating layers 1110a, 1110b, and 1110c to form the printed circuit board 10B in this embodiment is not limited by the above-described method.

Third passivation layers 1130a may be formed on the upper and lower surfaces of the printed circuit board 10B. The third passivation layers 1130a may protect first and third wiring layers 1120a and 1120c, junction pads 1210, 1220, and 1230, or the like, arranged adjacent to an outermost side in the insulating portion 1110B, among the wiring portion 1120B, from an external source. A material of the third passivation layers 1130a may be an insulating material. In this case, as the insulating material, a thermosetting resin such as an epoxy resin, a thermoplastic resin such as polyimide, or a mixture of these resins and an inorganic filler, e.g., ABF may be used, but the present disclosure is not limited thereto, and a solder resist (SR) including a photosensitive material may be used.

The first and second junction pads 1210 and 1220 may be formed on lower surfaces of the first and second recesses P1 and P2 to connect the first and second electronic component packages 10A and the printed circuit board 10B, respectively.

In this embodiment, lateral and lower surfaces of the recess P (e.g., P1 and P2) may refer to surfaces of the recess P in which the insulating portion 1110B of the printed circuit board 10B is exposed externally by the above-described recess formation process. The lower surface of the recess P (e.g., P1 and P2) may refer to a surface of the recess P disposed closest to an innermost side of the insulating portion 1110B, among surfaces from which the insulating portion 1110B is exposed. The third passivation layers 1130a may or may not be formed on the lateral surfaces of the first and second recesses P1 and P2. Referring to FIG. 3, the first and second junction pads 1210 and 1220 may be formed on the lower surfaces of the first and second recesses P1 and P2, respectively, and may be completely exposed from the insulating portion 1110B. Further, although not specifically illustrated, the first and second junction pads 1210 and 1220 may have a partial region embedded in the insulating portion 1110B and a remaining region exposed without being embedded.

A third junction pad 1230 may be formed to connect an electronic component 10C, other than the electronic component package 10A of this embodiment, to the insulating portion 1110B. As will be described later, the electronic component 10C may be in the form of a package including a plurality of electronic devices, as in the electronic component package 10A, or may be an individual electronic device. In the case of a package including a plurality of electronic devices, the electronic component 10C may include a passive device and an active device. In the case of an individual electronic device, the electronic component 10C may be a passive device or an active device. As a result, a larger number of electronic components or electronic component packages may be additionally mounted on the printed circuit board 10B.

An insulating material may be used as a material for the plurality of insulating layers 1110a, 1110b, and 1110c. As the insulating material, a thermosetting resin such as an epoxy resin, or a thermoplastic resin such as polyimide, and those including a reinforcing material such as an inorganic filler such as silica and/or glass fiber, etc in the resins may be used. For example, a prepreg, ABF, or the like may be used as the material for the plurality of insulating layers 1110a, 1110b, and 1110c.

A metal material may be used as a material for the plurality of wiring layers 1120a, 1120b, and 1120c. As the metal material, copper (Cu), aluminum (Al), silver (Ag), tin (Sn), gold (Au), nickel (Ni), lead (Pb), titanium (Ti), or an alloy thereof may be used. Each of the plurality of wiring layers 1120a, 1120b, and 1120c may perform various functions, depending on a design. For example, a ground pattern, a power pattern, a signal pattern, and the like may be included. Each of these patterns may have a line pattern, a plane pattern, or a pad pattern.

For example, a first through-via 1140a may connect a portion of the second wiring layer 1120b and a portion of the first wiring layer 1120a, arranged on an outermost side, based on an insulating layer in which the recess P is formed. The first through-via 1140a may collectively pass through the third insulating layer 1110c disposed on an outermost side of an insulating layer in which the recess P is formed. As materials for first and second through-vias 1140a and 1140b, copper (Cu), aluminum (Al), silver (Ag), tin (Sn), gold (Au), nickel (Ni), lead (Pb), titanium (Ti), or an alloy thereof may be used.

The plurality of wiring layers 1120a, 1120b, and 1120c, and the first and second through-vias 1140a and 1140b may be formed by a plating process, and, as a result, may include a seed layer that may be an electroless plating layer, and an electroplating layer formed based on the seed layer.

Substrate Structure

Referring to the drawings, a substrate structure 10 of the first embodiment of the present disclosure may include a printed circuit board 10B, a first electronic component package 10A, first external junction portions 810 and 820, and an electronic component 10C.

First external junction portions 810 and 820 may connect a first electronic component package 10A and first and second junction pads 1210 and 1220 to be described later. The first external junction portions 810 and 820 may be formed of solder balls. In this embodiment, for convenience of explanation, only the first external junction portions 810 and 820 may be provided, but the same description may be applied to a second external junction portion. For example, the substrate structure 10 may further include a second external junction portion connecting a second electronic component package 10A and the second junction pad 1220.

In this embodiment, an electronic component 10C formed on a printed circuit board 10B may be further included. When the electronic component 10C is an individual electronic device, not a package type, the electronic component 10C may be of the same type as or different types from first and second electronic devices 210 and 220. A thickness of the electronic component 10C disposed on the printed circuit board 10B may be greater than a thickness of a first electronic device module (210 and 220) . In this embodiment, since electronic devices may be disposed in an electronic component package, an entire size of a substrate structure may be reduced.

### Second Embodiment

FIG. 4 is a view schematically illustrating a substrate structure according to a second embodiment of the present disclosure.

Referring to FIG. 4, a substrate structure 10 including an electronic component package 10A according to this embodiment is different from the substrate structure 10 including the electronic component package 10A according to the first embodiment of the present disclosure, in terms of the fact whether a cover portion 1300 is present. Therefore, in describing this embodiment, only the cover portion 1300, different from the first embodiment of the present disclosure, will be described. For remaining configurations of this embodiment, the descriptions in the first embodiment of the present disclosure may be applied as they are.

Referring to FIG. 4, a substrate structure 10 including an electronic component package 10A according to this embodiment may include a cover portion 1300.

Referring to FIG. 4, the cover portion 1300 may be formed on an insulating portion 1110B of a printed circuit board 10B to cover first and second electronic component packages 10A and an electronic component 10C. The cover portion 1300 may be filled in first and second recesses P1 and P2. Since the cover portion 1300 covers the first and second electronic component packages 10A and the electronic component 10C, damage and separation of the first and second electronic component packages 10A and the electronic component 10C may be prevented from external impact. A material of the cover portion 1300 is not particularly limited as long as the material has insulating properties. For example, a thermosetting resin such as an epoxy resin, a thermoplastic resin such as polyimide, or resins including reinforcing materials such as glass fiber, glass cloth, glass fabric and/or inorganic fillers, together with these, such as a prepreg, Ajinomoto Build-up Film (ABF), and the like may be used.

### Third Embodiment

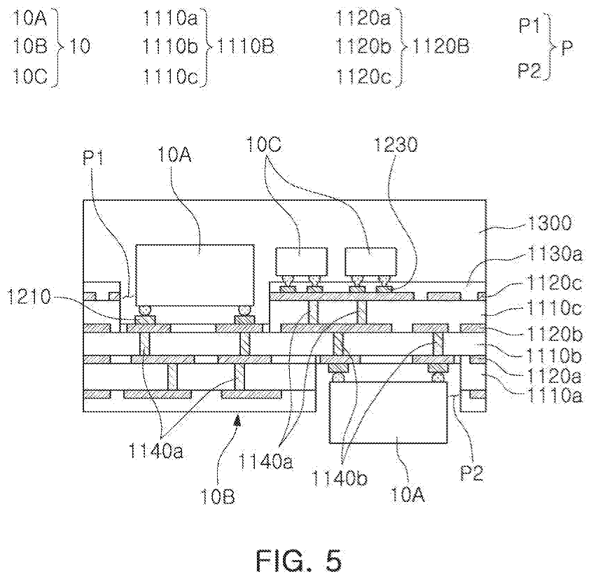

FIG. 5 is a view schematically illustrating a substrate structure according to a third embodiment of the present disclosure.

Referring to FIG. 5, a substrate structure 10 including an electronic component package 10A according to this embodiment is different from the substrate structure 10 including the electronic component package 10A according to the first embodiment of the present disclosure, in terms of the fact that a positional relationship of recesses P1 and P2 is different. Therefore, in describing this embodiment, only the positional relationship of the recesses P1 and P2, different from the first embodiment of the present disclosure, will be described. For remaining configurations of this embodiment, the descriptions in the first embodiment of the present disclosure may be applied as they are.

Referring to FIG. 5, in a case of a substrate structure 10 according to this embodiment, a first recess P1 may be formed on one surface of a printed circuit board 10B, and a second recess P2 may be formed on the other surface of the printed circuit board 10B, opposing the one surface of the printed circuit board 10B. The other surface of the printed circuit board 10B may refer to an upper surface of the printed circuit board 10B, arranged to oppose the above-described one surface. The other surface of the printed circuit board 10B may refer to a lowermost surface of the printed circuit board 10B in the thickness direction, formed along the first and second recesses P1 and P2, among surfaces of the printed circuit board 10B.

Referring to FIG. 5, a cover portion 1300 may cover only a first electronic component package 10A and an electronic component 10C, and may not further cover a second electronic component package 10A, but is not limited thereto.

In this embodiment, the first and second electronic component packages 10A may be also formed on the one surface and the other surface of the printed circuit board 10B, respectively. As a result, since a separation distance between the first and second electronic component packages 10A in the horizontal direction may be reduced, an entire size of the substrate structure 10 may be reduced.

Method of Manufacturing Electronic Component Package

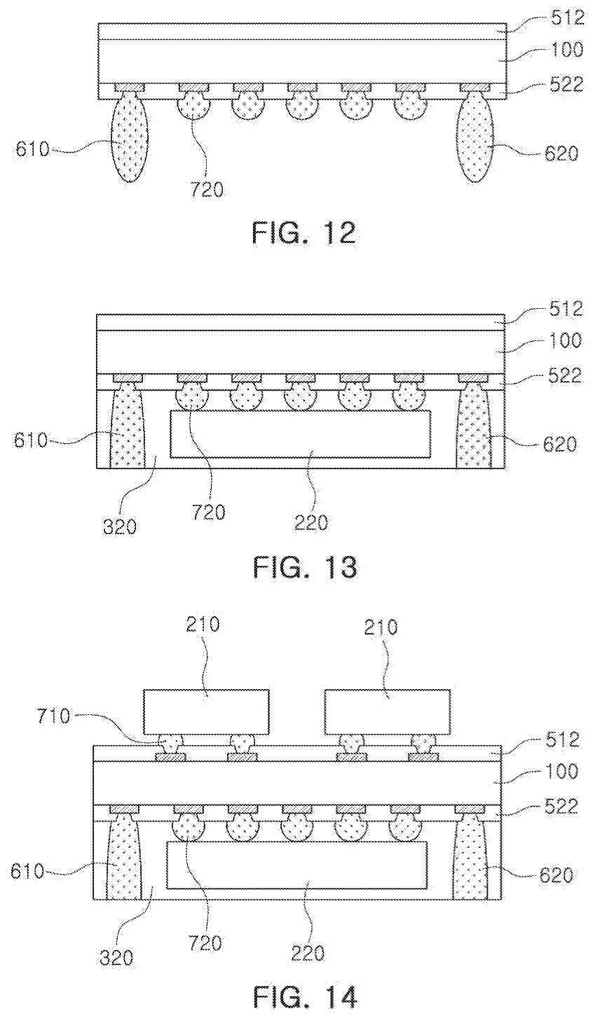

FIGS. 12 to 16 are process cross-sectional views schematically illustrating an example method of manufacturing the electronic component package of FIG. 6.

Referring to FIG. 12, a first substrate 100 may be prepared to have a solder-on paste. Passivation layers 512 and 522 may be formed with a solder resist on one surface and the other surface of the first substrate 100, and a solder may be formed on the other surface of the first substrate 100. Through this, a solder, which may be internal junction portion 720 and connection electrodes 610 and 620, may be first formed on the first substrate 100.

Referring to FIG. 13, a second electronic device 220 may be disposed on the other surface of the first substrate 100 on which a solder is formed, to be connected to the internal junction portion 720. After the second electronic device 220 is mounted on an electronic component package, a second encapsulation portion 320 may be formed. After the second encapsulation portion 320 is formed, the connection electrodes 610 and 620 may be ground to expose the connection electrodes 610 and 620 to a lower surface of the second encapsulation portion 320. As described above, in this embodiment, a process of forming the second encapsulation portion 320 may be omitted.

Referring to FIG. 14, a first electronic component 210 may be formed on the one surface of the first substrate 100. A passivation layer 512 may be formed on the one surface of the first substrate 100 with a solder resist, and a solder may be formed on the one surface of the first substrate 100. Through this, an active device and a passive device may be mounted on both of the surfaces of the first substrate 100.

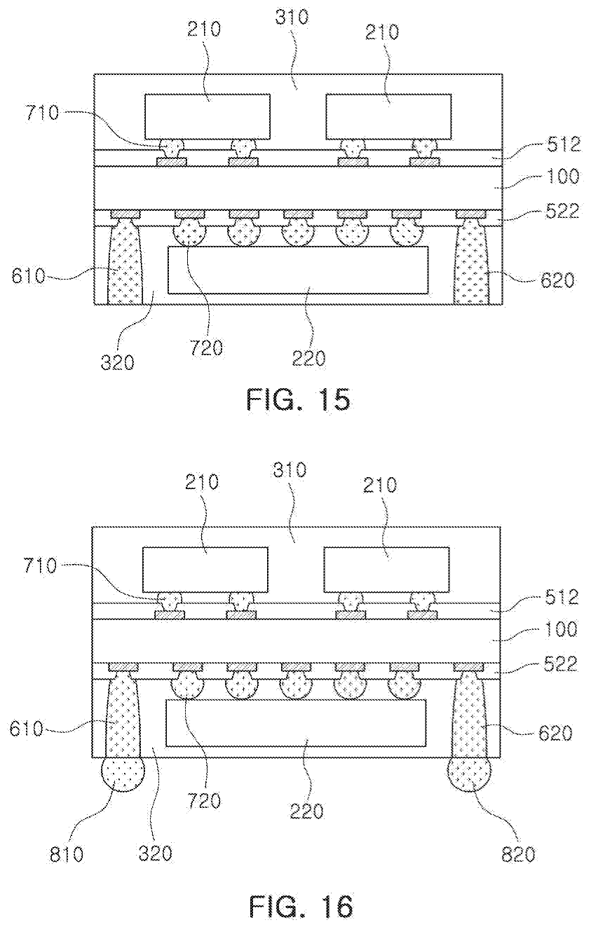

Referring to FIG. 15, a first encapsulation portion 310 may be disposed on the one surface of the first substrate 100 to cover the first electronic device 210. As described above, in this embodiment, a process of forming the first encapsulation portion 310 may be omitted.

Referring to FIG. 16, external junction portions 810 and 820 may be formed to mount the second electronic device 220 on a first junction pad 1210 of a substrate structure 10. As described above, the external junction portions 810 and 820 may be formed with a solder. Through this, the electronic component package 10A according to this embodiment may be electrically connected to the substrate structure 10.

First Modified Example of First Embodiment

FIG. 7 is a view schematically illustrating an electronic component package according to a first modified example of the first embodiment of the present disclosure.

Referring to FIG. 7, an electronic component package 20A according to this modified example is different from the electronic component package 10A according to the first embodiment of the present disclosure, in terms of the fact whether a cap portion 400 is present. Therefore, in describing this modified example, only the cap portion 400, different from the first embodiment of the present disclosure, will be described. For remaining configurations of this embodiment, the descriptions in the first embodiment of the present disclosure may be applied as they are.

Referring to FIG. 7, a cap portion 400 may be formed along outer surfaces of first and second encapsulation portions 310 and 320.

A cap portion 400 may be disposed on a surface of an electronic component package 20A according to this modified example, to block electromagnetic waves. In this modified example, the cap portion 400 may extend from surfaces of the first and second encapsulation portions 310 and 320 to a lateral surface of a first substrate 100. Therefore, the cap portion 400 may be electrically connected to a ground pad (not illustrated) or a ground layer (not illustrated), exposed from a region such as the lateral surface of the first substrate 100. The ground pad (not illustrated) or the ground layer (not illustrated) may be provided in a region such as the lateral surface of the first substrate 100.

In addition, the cap portion 400 may also be formed on a lower surface of the electronic component package 20A. The cap portion 400 disposed on the lower surface of the electronic component package 20A may be electrically connected to the cap portion 400 disposed on the lateral surface of the first substrate 100, or may be electrically connected to an external junction portion 800 connected to the ground pad. Meanwhile, the cap portion 400 disposed on the lower surface of the electronic component package 20A may be omitted, as necessary.

The cap portion 400 may be formed of a conductive material. The cap portion 400 may be formed by coating a resin material including conductive powder particles on surfaces of the first and second encapsulation portions 310 and 320 or forming a metal thin film. When the metal thin film is formed, various techniques such as sputtering, screen printing, vapor deposition, electrolytic plating, and electroless plating may be used. As a result, the cap portion 400 may be interposed between a plurality of electronic component packages 20A provided on a substrate structure 10, to block interference between the plurality of electronic component packages 20A.

Second Modified Example of First Embodiment

FIG. 8 is a view schematically illustrating an electronic component package according to a second modified example of the first embodiment of the present disclosure.

Referring to FIG. 8, an electronic component package 30A according to this modified example is different from the electronic component package 10A according to the first embodiment of the present disclosure, in terms of the fact that materials and structures of first and second connection electrodes 610 and 620 are different. Therefore, in describing the modified example, only the first and second connection electrodes 610 and 620, different from the first embodiment of the present disclosure, will be described. For remaining configurations of this embodiment, the descriptions in the first embodiment of the present disclosure may be applied as they are.

The first and second connection electrodes 610 and 620 may include a conductive material such as copper (Cu) or the like. In this modified example, the first and second connection electrodes 610 and 620 may be formed as a plating layer. Although not specifically illustrated, when a modified semi-additive process (MSAP) is used, the plating layer may be formed by plating a copper foil layer, an electroless copper plating layer, and an electrolytic copper plating layer of a first substrate 100 as a seed layer 101. Although not specifically illustrated, when a semi-additive process (SAP) is used, the plating layer may be formed by plating an electroless copper plating layer and an electrolytic copper plating layer separately formed on the first substrate 100 as the seed layer 101.

Typically, when an electronic component package or an electronic component is coupled to another electronic component or an external printed circuit board by connection pads 511 and 521 and a solder ball, as input/output (I/O) ratio increases, a pitch between the connection pads 511 and 521 or a pitch between the solder balls may be narrowed. Therefore, a problem may occur in that adjacent solder balls and adjacent first and second connection electrodes 610 and 620 are coupled to each other. In this modified example, the first and second connection electrodes 610 and 620 may be formed by plating, to prevent occurrence of a problem in which internal junction portions 710 and 720 and first and second connection electrodes 610 and 620 are coupled, and to implement a finer pitch. Further, although not specifically illustrated, the electronic component package 30A according to this modified example may use the first and second connection electrodes 610 and 620 themselves as external junction portions 810 and 820. Even in this case, a finer pitch may be implemented, as compared to a case in which the first and second connection electrodes 610 and 620 are formed of a solder.

Third Modified Example of First Embodiment

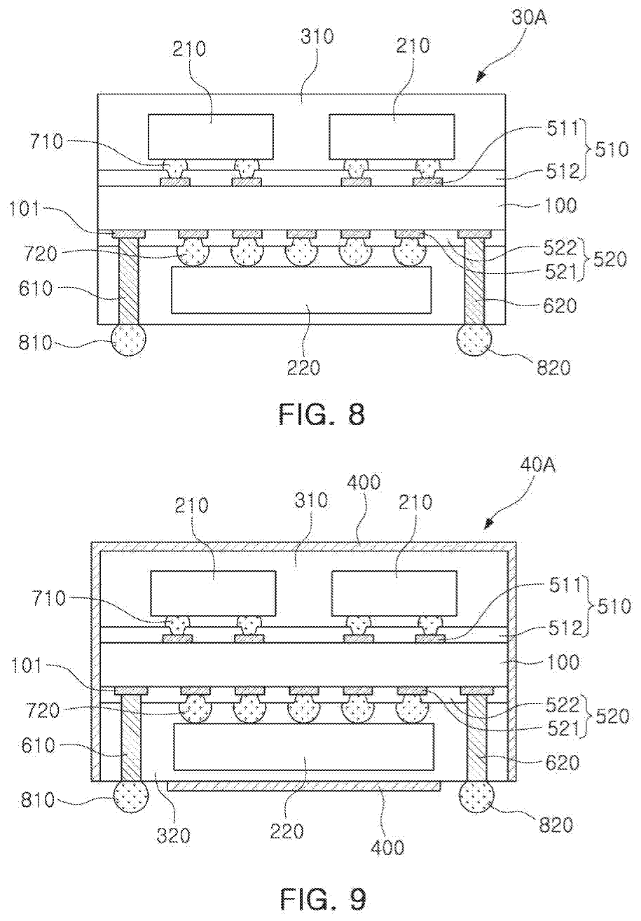

FIG. 9 is a schematic diagram illustrating an electronic component package according to a third modified example of the first embodiment of the present disclosure.

Referring to FIG. 9, an electronic component package 40A according to this modified example is different from the electronic component package 10A according to the first embodiment of the present disclosure, in terms of the fact that a cap portion 400 and first and second connection electrodes 610 and 620 are different. Therefore, in describing this modified example, only the cap portion 400 and the first and second connection electrodes 610 and 620, different from the first embodiment of the present disclosure, will be described. For remaining configurations of this embodiment, the descriptions in the first embodiment of the present disclosure may be applied as they are.

Referring to FIG. 9, an electronic component package 40A of this modified example may include a cap portion 400. With respect to the cap portion 400 of this modified example, the descriptions in the first modified example of the first embodiment may be applied.

Referring to FIG. 9, the electronic component package 40A of this modified example may include first and second connection electrodes 610 and 620 formed by plating. With respect to the first and second connection electrodes 610 and 620 of this modified example, the descriptions in the second modified example of the first embodiment may be similarly applied.

Fourth Modified Example of First Embodiment

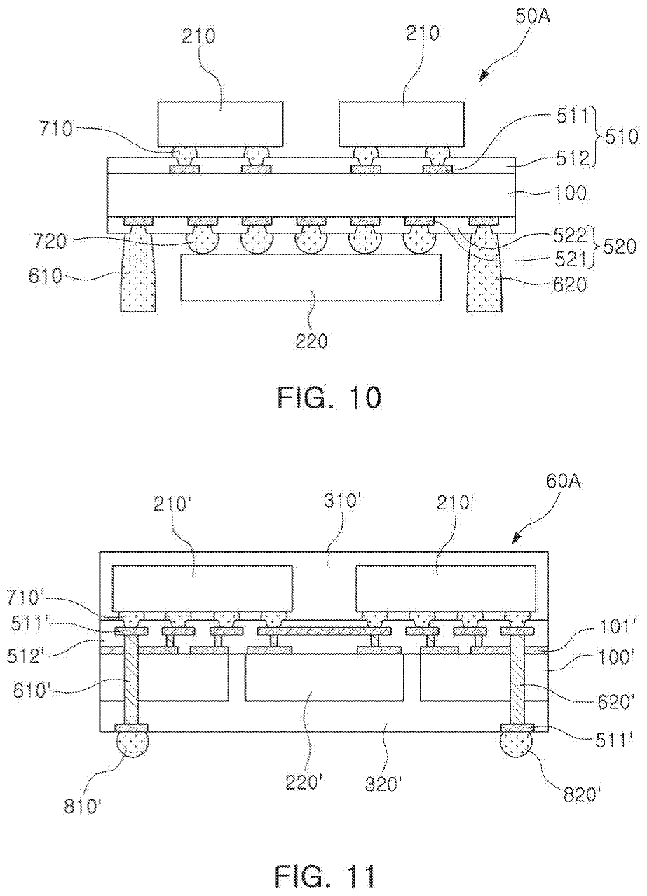

FIG. 10 is a view schematically illustrating an electronic component package according to a fourth modified example of the first embodiment of the present disclosure.

Referring to FIG. 10, an electronic component package 50A according to this modified example is different from the electronic component package 10A according to the first embodiment of the present disclosure, in terms of the fact whether first and second encapsulation portions 310 and 320 are present. Therefore, in describing the modified example, only the first and second encapsulation portions 310 and 320, different from the first embodiment of the present disclosure, will be described. For remaining configurations of this embodiment, the descriptions in the first embodiment of the present disclosure may be applied as they are.

Referring to FIG. 10, the electronic component package 50A may not include first and second encapsulation portions 310 and 320. After a second electronic device 220 is formed, a process of forming the second encapsulation portion 320 may be omitted, and after the first electronic device 210 is formed, a process of forming the first encapsulation portion 310 may be omitted.

Fifth Modified Example of First Embodiment

FIG. 11 is a schematic diagram illustrating an electronic component package according to a fifth modified example of the first embodiment of the present disclosure.

Referring to FIG. 11, an electronic component package 60A according to this modified example is different from the electronic component package 10A according to the first embodiment of the present disclosure, in terms of the fact that a first substrate 100′, a conductor layer 101′, connection electrodes 610′ and 620′, a connection pad 511′, and a second substrate 512′ are different. Therefore, in describing this modified example, only the first substrate 100′, the conductor layer 101′, the connection electrodes 610′ and 620′, the connection pad 511′, and the second substrate 512′, different from the first embodiment of the present disclosure, will be described. For remaining configurations of this embodiment, the descriptions in the first embodiment of the present disclosure may be applied as they are.

The first substrate 100′ may be a mainboard or a mother board. As the first substrate 100′, various known substrates such as a printed circuit board, a flexible substrate, a ceramic substrate, and a glass substrate may be used. The first substrate 100′ may include an insulating layer, a wiring layer, and a via electrically connecting the wiring layer. The first substrate 100′ may have a multilayer structure including a plurality of insulating layers, a plurality of wiring layers, and a plurality of vias.

The second substrate 512′ may be configured, in a manner similar to the first substrate 100′, and various known substrates such as a printed circuit board, a flexible substrate, a ceramic substrate, and a glass substrate may be used. The second substrate 512′ may be coupled to an upper surface of the first substrate 100′, and may be electrically connected to the first substrate 100′ by the conductor layer 101′. In this case, the conductor layer 101′ may be formed of a conductive material. The second substrate 512′ according to this modified example may be a multilayer substrate formed of a plurality of layers, and a wiring pattern for forming an electrical connection may be formed between each of the plurality of layers.

The conductor layer 101′ may be disposed on upper or lower surface of the first substrate 100′. The conductor layer 101′ may be provided to be electrically connected to the second substrate 512′. The conductor layer 101′ may contain at least one material selected from silver (Ag), palladium (Pd), aluminum (Al), nickel (Ni), titanium (Ti), gold (Au), copper (Cu), platinum (Pt), and the like, or a mixture of two or more thereof. The conductor layer 101′ may be formed by a known method, and may be formed by, for example, electrolytic copper plating or electroless copper plating. More specifically, the conductor layer 101′ may be formed by a method such as a chemical vapor deposition (CVD) process, a physical vapor deposition (PVD) process, a sputtering process, a subtractive process, an additive process, a semi-additive process (SAP), a modified semi-additive process (MSAP), or the like, but is not limited thereto.

The connection electrodes 610′ and 620′ may be formed to pass through a region of the second substrate 512′, the conductor layer 101′, the first substrate 100′, and a second encapsulation portion 320′. In this embodiment, the first and second connection electrodes 610′ and 620′ may be formed of a plating layer. The first and second connection electrodes 610′ and 620′ may be formed to have a post shape including a conductive material such as copper (Cu) or the like.

The connection pad 511′ disposed below the first substrate 100′ may be disposed in the second encapsulation portion 320′, to electrically connect the second substrate 512′ and external junction portions 810′ and 820′. Therefore, the second substrate 512′ may be electrically connected to the substrate structure 10 on which the electronic component package 60A is mounted, by the conductor layer 101′, the first substrate 100′, the connection pad 511′, and the external junction portions 810′ and 820′. The connection pad 511′ may be formed of a conductive material such as a solder or a conductive resin, but is not limited thereto.

In the present disclosure, for convenience, expressions such as a lateral portion, a lateral surface, and the like may be used to refer to a left/right direction or a surface in the direction, based on the drawings, expressions such as an upper side, an upper portion, an upper surface, and the like may be used to refer to an upward direction or a surface in the direction, based on the drawings, and expressions such as a lower side, a lower portion, a lower surface, and the like may be used to refer to a downward direction or a surface in the direction, based on the drawings. In addition, positioning at the lateral portion, the upper side, the upper portion, the lower side, or the lower portion may be used as a concept including not only that a component is in direct contact with a reference component in a corresponding direction, but also that a component is positioned in the corresponding direction but is not in direct contact with the reference component. However, for convenience of explanation, the above expressions have been defined based on a direction, and the scope of the claims is not particularly limited by the description of this direction, and the upper/lower concepts may be changed at any time.

The term of “connect” or “connection” in the present disclosure may be not only a direct connection, but also a concept including an indirect connection through an adhesive layer or the like. In addition, the term “electrically connected” or “electrical connection” in the present disclosure is a concept including both a physical connection and a physical non-connection. Also, the expressions of “first,” second,” etc. in the present disclosure are used to distinguish one component from another, and do not limit the order and/or importance of the components. In some cases, without departing from the spirit of the present disclosure, a first component may be referred to as a second component, and similarly, a second component may be referred to as a first component.

The expression “example”, except in relation to experimental examples, used in this specification does not refer to the same embodiment to each other, but may be provided for emphasizing and explaining different unique features. However, the above-mentioned examples do not exclude that the above-mentioned examples are implemented in combination with the features of other examples. For example, although the description in a specific example is not described in another example, it can be understood as an explanation related to another example, unless otherwise described or contradicted by the other example.

The terms used in the present disclosure are used only to illustrate various examples and are not intended to limit the present inventive concept. Singular expressions include plural expressions unless the context clearly dictates otherwise.

According to an embodiment of the present disclosure a mounting region of electronic components and an overall thickness of a printed circuit board may be reduced.

According to another embodiment of the present disclosure, shielding characteristics between electronic component packages in a small-sized printed circuit board may be improved.

While example embodiments have been illustrated and described above, it will be apparent to those skilled in the art that modifications and variations could be made without departing from the scope of the present disclosure as defined by the appended claims.

What is claimed is:

1. A substrate structure comprising:
a printed circuit board including a first recess and a first junction pad disposed on a lower surface of the first recess;
a first electronic component package disposed in the first recess, and including a first substrate and a first electronic device module disposed on at least one surface of the first substrate; and
a first external junction portion connecting the first electronic component package and the first junction pad.

2. The substrate structure of claim 1, further comprising an electronic component disposed on the printed circuit board.

3. The substrate structure of claim 2, wherein a thickness of the electronic component is greater than a thickness of the first electronic device module.

4. The substrate structure of claim 2, wherein the printed circuit board further comprises a second recess spaced apart from the first recess, and a second junction pad disposed on a lower surface of the second recess,
wherein the substrate structure further comprises:
a second electronic component package disposed in the second recess and including a second substrate and a second electronic device module disposed on at least one surface of the second substrate; and
a second external junction portion connecting the second electronic component package and the second junction pad.

5. The substrate structure of claim 4, wherein the first and second recesses are recessed from one surface of the printed circuit board to be spaced apart from each other.

6. The substrate structure of claim 4, wherein the first recess is recessed from one surface of the printed circuit board, and
the second recess is recessed from the other surface of the printed circuit board, opposing the one surface of the printed circuit board.

7. The substrate structure of claim. 4, wherein a depth of the first recess is different from a depth of the second recess.

8. The substrate structure of claim 4, further comprising a cover portion disposed on the printed circuit board to cover the first electronic component package and the electronic component.

9. The substrate structure of claim 8, wherein the cover portion further covers the second electronic component package.

10. The substrate structure of claim 1, wherein the first electronic device module comprises a first electronic device disposed on one surface of the first substrate, and a second electronic device disposed on the other surface, opposing the one surface of the first substrate.

11. The substrate structure of claim 10, wherein the first electronic device comprises a passive device, and the second electronic device comprises an active device.

12. The substrate structure of claim 10, wherein the first electronic component package further comprises a first encapsulation portion disposed on the one surface of the first substrate to cover the first electronic device.

13. The substrate structure of claim 10, wherein the first electronic component package further comprises a second encapsulation portion disposed on the other surface of the first substrate to cover the second electronic device.

14. The substrate structure of claim 10, wherein the first electronic component package further comprises:
first and second encapsulation portions respectively disposed on the one surface and the other surface of the first substrate, and
a cap portion extending along outer surfaces of the first and second encapsulation portions.

15. The substrate structure of claim 10, wherein the first electronic component package further comprises:
a first connection structure disposed on the one surface of the first substrate and disposed between the first substrate and the first electronic device, and
a second connection structure disposed on the other surface of the first substrate and disposed between the first substrate and the second electronic device.

16. The substrate structure of claim 1, wherein the first electronic component package further comprises first and second connection electrodes connecting the first substrate and the first junction pad.

17. The substrate structure of claim 16, wherein the first and second connection electrodes include a plating layer.

18. The substrate structure of claim 1, wherein the first external junction portion includes a solder ball disposed between the first electronic component package and the lower surface of the first recess.

19. A substrate structure comprising:
a printed circuit board including a recess and a junction pad disposed on a lower surface of the recess; and
an electronic component package disposed in the recess and including a substrate and first and second electronic devices respectively disposed on both surfaces of the substrate.

20. The substrate structure of claim 19, wherein the first electronic device comprises a passive device, and the second electronic device comprises an active device.
